(19) United States
(12) Patent Application Publication
(10) Pub. No.: US 2022/0271118 A1
(43) Pub. Date: Aug. 25, 2022

(54) METHOD AND APPARATUS RELATED TO CONTROLLABLE THIN FILM RESISTORS FOR ANALOG INTEGRATED CIRCUITS

(71) Applicant: SEMICONDUCTOR COMPONENTS INDUSTRIES, LLC, Phoenix, AZ (US)

(72) Inventors: Rick Carlton JEROME, Washougal, WA (US); Gordon M. GRIVNA, Mesa, AZ (US); Kevin Alexander STEWART, Gresham, OR (US); David T. PRICE, Gresham, OR (US); Jeffrey Peter GAMBINO, Gresham, OR (US)

(73) Assignee: SEMICONDUCTOR COMPONENTS INDUSTRIES, LLC, Phoenix, AZ (US)

(21) Appl. No.: 17/249,279

(22) Filed: Feb. 25, 2021

(51) Int. Cl. H01L 49/02; H01C 7/00

(52) U.S. Cl. CPC H01L 28/24; H01C 7/006

(57) ABSTRACT

An integrated circuit die includes a silicon chromium (SiCr) thin film resistor disposed on a first oxide layer. The SiCr thin film resistor has a resistor body and a resistor head. A second oxide layer overlays the SiCr thin film resistor. The second oxide layer has an opening exposing a surface of the resistor head. A metal pad is disposed in the opening in the second oxide layer and is contact with the surface of the resistor head exposed by the opening. Further, an interlevel dielectric layer is disposed on the second oxide layer overlaying the SiCr thin film resistor. A metal-filled via extends from a top surface of interlevel dielectric layer through the interlevel dielectric layer and contacts the metal pad disposed in the opening in the second oxide layer.

### TECHNICAL FIELD

This description relates to thin film resistors.

### BACKGROUND

Integrated analog circuits (e.g., current-sense amplifiers with low offset voltage and low gain error, voltage references, and current mirrors) can include multiple thin film resistors as integrated circuit elements. In many instances, the thin film resistors are sputtered thin film resistors. High performance integrated analog circuits can demand thin film resistors with or more stringent specifications (e.g., high accuracy resistor-to-resistor mismatch (˜0.01% mismatch), low temperature coefficient of resistance (<+/−50 ppm/C), and low high-temperature operating life (HTOL) reliability drift (<0.1%)) for the high performance.

### SUMMARY

An integrated circuit die includes a silicon chromium (SiCr) thin film resistor disposed on a first oxide layer. The SiCr thin film resistor includes a resistor body and a resistor head. A second oxide layer overlays the SiCr thin film resistor. The second oxide layer has an opening exposing a surface of the resistor head. A metal pad disposed in the opening in the second oxide layer and is in contact with the surface of the resistor head exposed by the opening. An interlevel dielectric layer is disposed on the second oxide layer overlaying the SiCr thin film resistor, and a metal-filled via extends from a top surface of interlevel dielectric layer through the interlevel dielectric layer and contacts the metal pad disposed in the opening in the second oxide layer.

An integrated circuit die includes a silicon chromium (SiCr) thin film resistor having a resistor body and a resistor head disposed on a first oxide layer. the SiCr thin film resistor; A protective dielectric layer overlays the SiCr thin film resistor. An interlevel dielectric layer is disposed on the protective dielectric layer overlaying the SiCr thin film resistor; and a metal-filled via extends from a top surface of interlevel dielectric layer through the interlevel dielectric layer and the protective dielectric layer and contacts the resistor head of SiCr thin film resistor.

An integrated circuit die includes a silicon chromium (SiCr) thin film resistor having a resistor body and a resistor head disposed on a first oxide layer. An interlevel dielectric layer is disposed on a dielectric layer overlaying the SiCr thin film resistor. A metal-filled via extends from a top surface of interlevel dielectric layer through the interlevel dielectric layer and contacts the resistor head of SiCr thin film resistor. The metal-filled via terminates at a landing pad disposed in the die.

An integrated circuit die includes an interlevel dielectric (ILD) layer disposed on a substrate. The ILD layer includes a first metal level disposed on the substrate. A metal-filled via extends from a top surface of the ILD layer through the ILD layer to contact the first metal level. A silicon chromium (SiCr) thin film resistor is disposed on the top surface of the ILD layer with a bottom surface of the SiCr thin film resistor being in contact with the metal-filled via extending from the first metal level to the top surface of the ILD layer.

A method includes forming an interlayer dielectric (ILD) layer including a first metal level on a semiconductor substrate, forming a first oxide layer on the ILD layer and forming a SiCr thin film on the first oxide layer. The method further includes forming a second oxide layer on the SiCr thin film, patterning and etching openings in the second oxide layer to expose portions of the SiCr thin film, depositing a titanium nitride (TiN) layer and a silicon oxynitride (SiON) overlayer over the patterned second oxide layer. The method further included patterning and etching the titanium nitride (TiN) layer and silicon oxynitride (SiON) overlayer to form contact pads contacting the SiCr thin film through the openings in the second oxide layer, and patterning and etching the second oxide layer and the SiCr thin film to define a SiCr resistor.

The details of one or more implementations are set forth in the accompanying drawings and the description below. Other features will be apparent from the description and drawings, and from the claims.

### BRIEF DESCRIPTION OF THE DRAWINGS

FIG. 1A illustrates an example SiCr thin film resistor.

FIG. 1B illustrates an example set of three masks.

FIG. 2 illustrates a portion of a backend structure of an integrated circuit die.

FIGS. 3 and 4 illustrate a resistor portion of the backend structure of FIG. 2.

FIGS. 5 through 9 illustrate a resistor portion of an example backend structure.

FIGS. 10 through 12 illustrate a portion of an example backend structure.

FIG. 13 illustrates an example method for integrating a SiCr resistor in a backend structure.

FIGS. 14A through 14F illustrate a backend structure disposed on semiconductor substrate at different stages of fabrication.

### DETAILED DESCRIPTION

A thin film resistor may be an element in an integrated circuit (IC) formed on a semiconductor substrate. The thin film resistor may, for example, be a sputtered thin film resistor. An example sputtered thin film resistor may have an amorphous body made of a silicon-chromium (SiCr) compound or alloy, and is referred to herein as an SiCr resistor. In a vertically integrated system (VIS), the SiCr resistor may be formed in an interlevel dielectric layer amidst a plurality of metallization and via metallization layers disposed on a semiconductor device die. The SiCr resistor may be formed and integrated in IC using semiconductor fabrication processes including, for example, lithographic patterning, material deposition, and material etching or removal techniques. The material etching or removal techniques may include, dry etching, wet etching, and chemical-mechanical polishing (CMP) techniques, etc.

The disclosure herein describes different example integrated circuit die structures, and different methods for integrating SiCr resistors in the integrated circuit die structures. The methods may preserve (substantially preserve) properties of as-formed SiCr resistors, for example, by preserving the composition, the amorphous nature, and surface interface structures of the as-formed SiCr resistors during processes integrating the as-formed SiCr resistors in the integrated circuit die structures. In the disclosed structures and methods, the surfaces (e.g., top and bottom surfaces) of the resistor are protected from damage by avoiding (or minimizing) exposure of the surfaces to etchants (that may be used to define or fabricate other components of the integrated circuit die structures).

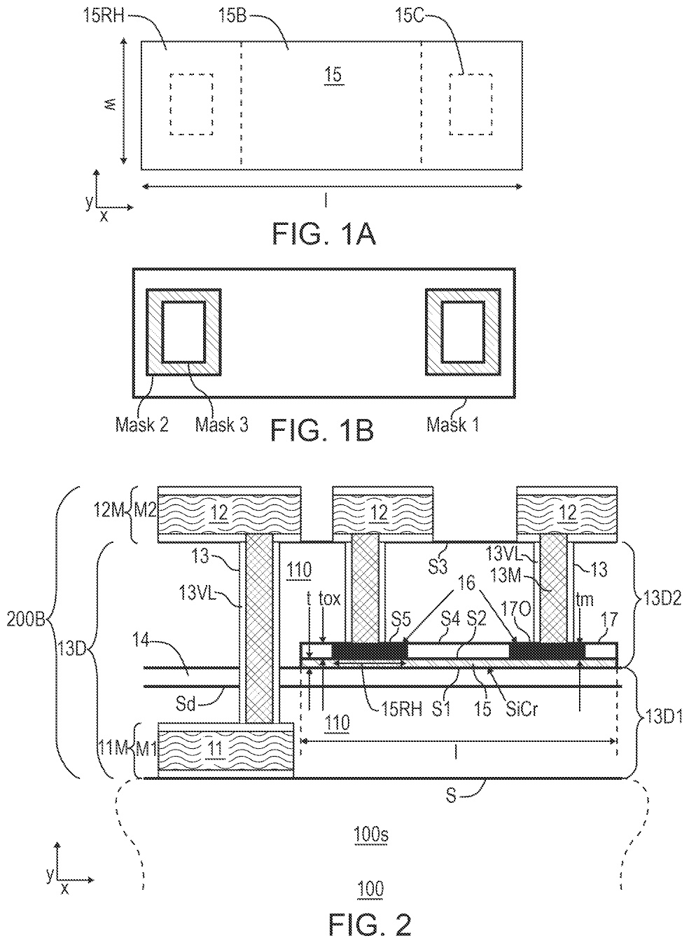

FIG. 1A shows an example SiCr resistor 15. SiCr resistor 15 may be formed from a thin film of materials sputtered on a substate. The materials may include silicon and chromium. SiCr resistor 15 may formed generally as a rectangular strip of thin film having a length 1 (e.g., in an x direction), a width w (in a y-direction), and a thickness t (in a z direction perpendicular to the page of FIG. 1). In example implementations, length 1 may be about 1 micrometer to about 100 micrometers, width w may be about 1 micrometer to about 20 micrometers, and thickness t may be about 50 angstroms to about 120 angstroms. SiCr resistor 15 may be formed as a thin film with an amorphous silicon-chromium composition. In some example implementations, SiCr resistor 15 may be formed by sputtering a mixture of silicon, chromium, and carbon or other elements from a single sputtering target to form the amorphous silicon-chromium composition. In some example implementations, SiCr resistor 15 may be formed by co-sputtering different elements (e.g., silicon, chromium, carbon, and or other elements) from separate sputtering targets to form the amorphous silicon-chromium composition. In some implementations, SiCr resistor 15 may, for example, include a small percentage of carbon (e.g., about 5% to 15% by weight) or other elements. The small percentage of carbon may help maintain the amorphous nature and properties of SiCr resistor 15.

SiCr resistor 15 may be used in an integrated circuit, for example, as a two-terminal circuit element, by making electrical contact with resistor portions (e.g., resistor head 15RH) on two ends of a body portion (e.g., resistor body 15B). The electrical contact may be made using interconnecting conductive structures (e.g., contact pads, terminal wires, etc.) with portions (e.g., contact regions 15C) of resistor heads 15RH on the two ends of resistor body 15B.

Fabrication of SiCr resistor 15 from a sputtered thin film, and integration of SiCr resistor 15 in a semiconductor integrated circuit die, may involve use of a set of one or masks (photomask) to lithographically pattern and define different regions of the resistor. FIG. 1B shows an example set of three masks (e.g., Mask 1, Mask 2 and Mask 3) that can be used to lithographically pattern and define different regions of the resistor in an integrated circuit die. Mask 1 may, for example, be used to define the shape and dimensions of SiCr resistor 15 during fabrication from a sputtered thin film. Mask 3 may be used to define resistor head portions (e.g., resistor head 15RH), and Mask 2 may be used to define resistor contact portions (e.g., contact regions 15C) that may be used for interconnections to the SiCr resistor in the integrated circuit die.

SiCr resistor 15 (shown in FIG. 1A) made from the sputtered thin film can be integrated in different example integrated circuit die structures (as shown, e.g., in FIGS. 2 through 12, etc.) using different integration methods. The integration methods may preserve (substantially preserve) properties of as-formed SiCr resistors, for example, by preserving the composition, the amorphous nature, and surface interface structures of the as-formed SiCr resistors during processes integrating the as-formed SiCr resistors in the integrated circuit die structures. In the disclosed structures and methods, the surfaces (e.g., top and bottom surfaces) of the resistor are protected from damage by avoiding (or minimizing) exposure of the surfaces to etchants (that may be used to define or fabricate other components of the integrated circuit die structures).

FIG. 2 shows a cross sectional view of a portion of a backend structure 200B of an integrated circuit die 100, including an example SiCr resistor 15. SiCr resistor 15 may be a sputtered thin film resistor. SiCr resistor 15 may, for example, be a generally rectangular strip of thin film material having length 1 (e.g., in an x direction), thickness t (e.g., in a y direction), and widths (e.g., widths wb, wrh, FIG. 3) in a z direction perpendicular to the page of FIG. 2. In example implementations, length 1 may be between about 1 micrometer to about 100 micrometers, width w may be between about 1 micrometer to about 20 micrometers, and thickness t may be between about 50 angstroms to about 120 angstroms. In example implementations, SiCr resistor 15 may be formed by sputtering or co-sputtering silicon and chromium materials to form an amorphous silicon-chromium composition. In some implementations, SiCr resistor 15 may include a small percentage of carbon (e.g., between about 5% and 15% by weight).

As shown in FIG. 2, backend structure 200B may be disposed on a top surface S of a semiconductor substrate 100s including integrated circuit die 100. Backend structure 200B may include metallization layers 11M and 12M that correspond, for example, to a first metal level 11 and a second metal level 12, respectively, of integrated circuit die 100. Metallization layers 11M and 12M may be disposed in an interlevel dielectric layer 13D on a top surface S of semiconductor substrate 100s. Interlevel dielectric layer 13D may include sub interlevel dielectric layers 13D1 and 13D2 with sub interlevel dielectric layer 13D1 disposed on top surface S of semiconductor substrate 100s, and sub interlevel dielectric layer 13D2 disposed on top surface Sd of sub interlevel dielectric layer 13D1. Metallization layer 12M including second metal level 12 may be disposed on a top surface S3 of sub interlevel dielectric layer 13D2.

A dielectric layer (e.g., an oxide layer 14) may cap or overlay sub interlevel dielectric layer 13D1. SiCr resistor 15 may be formed on top of oxide layer 14 in interlevel dielectric layer 13D. SiCr resistor 15 may have a bottom surface S1 (resting on oxide layer 14) and a top surface S2. Another dielectric layer (e.g., an oxide layer 17) may cap or overlay SiCr resistor 15. Oxide layer 17 may include openings 17O that expose top surface S2 of SiCr resistor. A metal pad 16 (e.g., a tungsten (W) pad) may be disposed on top surface S2 in openings 17O for electrical contact with SiCr resistor 15 in a region (e.g., resistor head 15RH) of the SiCr resistor (to form, e.g., a terminal of the resistor). Metal pad 16 (e.g., a tungsten (W) pad) may be disposed in direct contact with top surface S2 of SiCr resistor 15 with or without the presence of any intermediate layer (e.g., an adhesive or barrier layer such as a TiN layer) between metal pad 16 and the silicon-chromium material of as-formed SiCr resistor 15.

In example implementations, oxide layer 17 may be disposed directly and patterned on top surface S2 of SiCr resistor 15. Oxide layer 17 may be made of silicon oxide (SiOx) using a tetraethyl orthosilicate (TEOS) deposition process (TEOS deposition). Oxide layer 17 may have a top surface S4 and a thickness tox. In example implementations, thickness tox may be in a range of 1000A to 4000A (e.g., 1000A). An opening (e.g., opening 17O) may be formed in patterned oxide layer 17 by lithographically patterning oxide layer 17 (using a single photo mask, e.g., Mask 3, FIG. 1B)), and wet etching the patterned oxide layer 17. The wet etching may, for example, use a dilute hydrofluoric acid (HF) etchant.

In example implementations, metal pad 16 (e.g., a tungsten (W) pad) may be formed by sputtering metal (e.g., W) to fill the opening (e.g., opening 17O) in patterned oxide layer 17, followed by CMP planarization (e.g., W-CMP) of the sputtered metal.

Metal pad 16 (e.g., a tungsten (W) pad) may have a top surface S5 and thickness tm. After CMP planarization, metal pad 16 thickness tm may be about a same as thickness tox (e.g., 1000A) of patterned oxide layer 17, and top surface S5 of metal pad 16 and top surface S4 of patterned oxide layer may be about coplanar.

The different metal levels in backend structure 200B (e.g., metal level 12 and metal level 11, and metal level 12 and metal pad 16 on SiCr resistor 15) may be interconnected by metal-filled vias 13. In example implementations, metal-filled vias 13 may be vias lined with a liner 13VL and filled with a metal 13M. In example implementations, liner 13VL may, for example, be a titanium nitride (TiN) liner, and metal 13M may, for example, be W.

In an example implementation, forming metal-filled vias 13 to contact metal pad 16 on SiCr resistor 15 may involve etching vias from top surface S3 through sub interlevel dielectric layer 13D2 to surface S5 of metal pad 16, lining sidewalls of the vias with liner 13VL, and filling the vias with metal 13M to contact metal pad 16.

In an example implementation, etching the vias may involve etching with uniform depth precision across substrate 100s to make uniform contact with multiple SiCr resistors 15 that may be formed on substrate 100s.

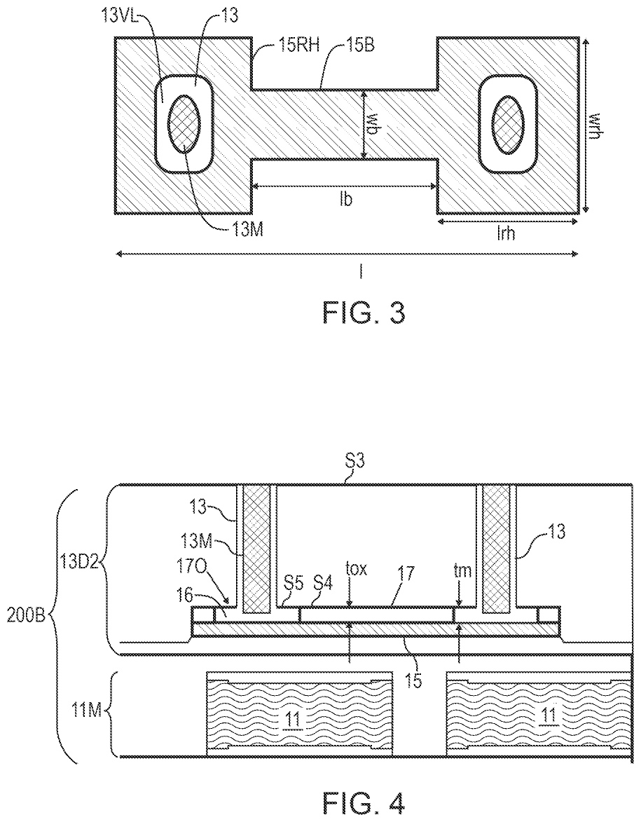

FIG. 3 shows, for example, a plan view of a resistor portion of backend structure 200B of FIG. 2. The plan view shown in FIG. 3 is taken, for example, looking down at top surface S3 of sub interlevel dielectric layer 13D2 in FIG. 2. FIG. 4 shows, for example, a cross sectional view of the resistor portion of backend structure 200B shown in FIG. 2.

As shown FIG. 3, SiCr resistor 15 may be a thin film strip with a length 1. SiCr resistor 15 may include a resistor body 15B (having a length lb and a width wb) and resistor head portions 15RH (having a length lrh and a width wrh) at two ends of the resistor body 15B. As shown in FIG. 4, metal-filled vias 13 (as previously described with reference to FIG. 2) extend from top surface S3 through sub interlevel dielectric layer 13D2 to about top surface S4 of patterned oxide layer 17. Metal 13M in the metal-filled vias 13 can establish contact with SiCr resistor through metal pad 16 (via contact with resistor head 15RH) of the SiCr resistor.

In an example implementation, an example SiCr resistor 15 may include a 50A to 100A thick amorphous SiCr sputtered thin film with a weight % of Cr between 40% and 60%, and a weight % of C between 5% and 15%. The amorphous SiCr sputtered thin film may have a resistivity of about 750 ohm/square to about 1500 ohm/square. Resistor-to-resistor mismatch (between multiple resistors in integrated circuit die 100) may be ˜0.01% (mean+3-sigma) for 5×50 sq. μm resistors (i.e., 1 ohm out of 10,000 ohms). A temperature coefficient of resistance may be less than about +/−150 ppm/C. SiCr resistor 15 may have an HTOL reliability drift of less than about 0.1%, and a high temperature storage life (HTSL) of reliability drift of less than about 0.1%.

In the example backend structure 200B described above with reference to FIGS. 2-4, the sputtered metal (in metal pad 16) fully fills a depth of opening 17O so that top surface S5 of metal pad 16 is about coplanar with top surface S4 of patterned oxide layer 17 (in other words, metal pad 16 and patterned oxide layer 17 have about a same thickness, tm=tox).

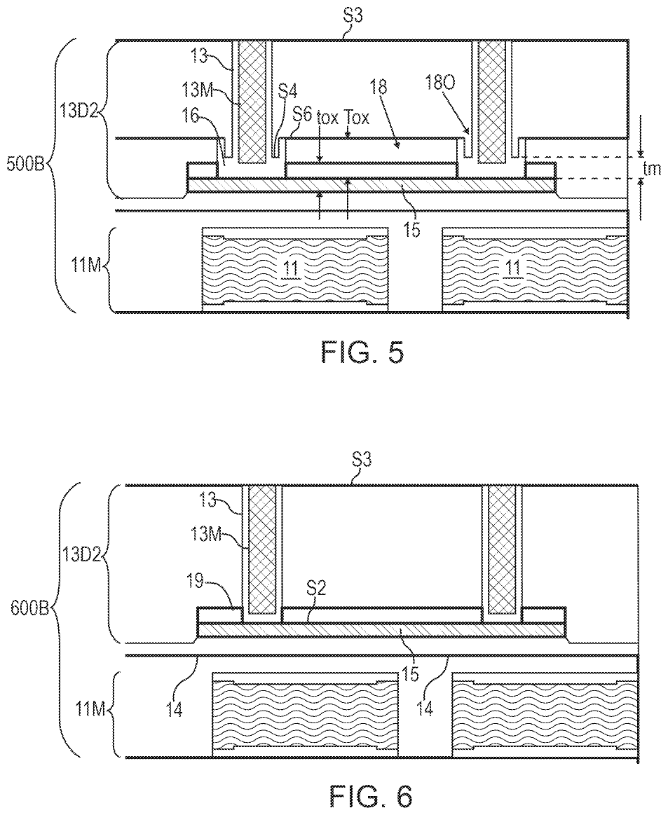

In some example implementations, an oxide layer (e.g., oxide layer 18, FIG. 5) with a larger oxide thickness (e.g., Tox) than the thickness tox of patterned oxide layer 17 may be disposed on SiCr resistor 15 to protect surface S2. An opening (e.g., opening 180), like opening 17O in FIGS. 3 and 4, may be patterned and etched in oxide layer 18 to receive sputtered metal to form metal pad 16 in the opening. Metal sputtered (for metal pad 16) in opening 180 may only partially fill a depth of opening 180 so that thickness tm of metal pad 16 in opening 180 is less than the thickness Tox of patterned oxide layer 18.

FIG. 5 shows a cross-sectional view of a resistor portion of an example backend structure 500B in which a thickness Tox of a patterned oxide layer 18 (e.g., a blanket deposited SiOx oxide layer) deposited on SiCr resistor 15 is larger than the thickness tox of patterned oxide layer 17 shown in FIGS. 2 and 4. In the example backend structure 500B shown in FIG. 4, metal pad 16 partially fills opening 180 in oxide layer 18 so that top surface S5 of metal pad 16 is below top surface S6 of patterned oxide layer 18 (in other words, metal pad 16 has a thickness tm that is smaller than the thickness Tox of patterned oxide layer 18). In example implementations, thickness Tox may be about 2500A and thickness tm may be in a range of about 1000A to 1500A.

As discussed previously (FIGS. 1-3), metal 13M in metal-filled vias 13 can establish contact with SiCr resistor 15 through metal pad 16 disposed in opening 180 (in oxide layer 18) in contact with resistor head 15RH of the SiCr resistor.

The larger thickness (i.e., Tox) of oxide layer 18 (FIG. 5) disposed on top surface S2 of the SiCr resistor 15 protects the top surface S2 of the SiCr resistor 15 more than a protection afforded by the smaller thickness (i.e., tox) of oxide layer 17 (FIGS. 2 and 4).

In some example implementations, contact with SiCr resistor 15 may be made direct contact of metal 13M (e.g., metal-filled vias) with SiCr materials of the SiCr resistor without using intervening metal pads 16 between the metal-filled vias and resistor head 15RH of the SiCr resistor.

As an example, FIG. 6 shows a cross sectional view of a portion of a backend structure 600B of an integrated circuit die 100, including an example SiCr resistor 15 in direct contact with metal vias for interconnection.

As shown in FIG. 6, a protective layer 18 (e.g., a silicon nitride layer or other layer with etch stopping capability) may be deposited on top surface S2 of SiCr resistor 15. Layer 18 may, for example, be a few hundred angstroms (e.g., 500 A) thick. Metal-filled vias 13 may extend from top surface S3 of sub interlevel dielectric layer 13D2 and reach and terminate at SiCr resistor 15. Forming metal-filled vias 13 to contact SiCr resistor 15 may involve precision depth etching of the vias from top surface S3 through sub interlevel dielectric layer 13D2 to surface S2 of SiCr resistor 15. The etch stopping capability of layer 18 (e.g., silicon nitride layer) relative to via etchants (oxide etchants) may stop via etching at layer 18 and aid in depth control. A downstream nitride etch may be used to clear the insides of the vias of silicon nitride material before the vias are filled with metal (e.g., metal 13M). Metal 13M in metal-filled vias 13 may directly contact SiCr resistor 15 (without the intervening metal pad 16 used in the foregoing example implementations of backend structures 200B, and 500B (FIGS. 2 through 5)).

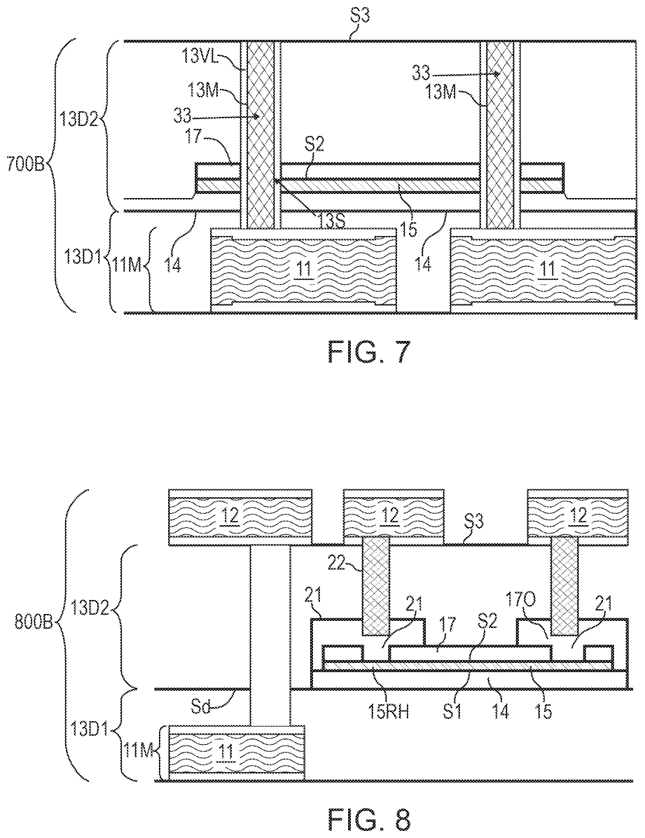

In some example implementations, contact with SiCr resistor 15 may be made through sidewalls of metal-filled vias (e.g., metal-filled vias 33) passing through SiCr resistor 15. As an example, FIG. 7 shows a cross sectional view of a portion of a backend structure 700B of integrated circuit die 100, including an example SiCr resistor 15 in direct contact with metal through via sidewalls.

As shown in FIG. 7, metal-filled vias 33 may extend from top surface S3 of sub interlevel dielectric layer 13D2, punch through SiCr resistor 15, and land on (i.e., stop on) a first metal level 11 in metallization layer 11M. Metal-filled vias 33, like metal-filled vias 13, may be lined with liner 13VL and filled with metal 13M. Metal 13M in the vias may contact SiCr resistor 15 through sidewall portions 13S of the vias.

In some example implementations, contact with SiCr resistor 15 may be made using a metal plug (e.g., a W plug) extending through sub interlevel dielectric layer 13D1 or sub interlevel dielectric layer 13D2. As an example, FIG. 8 shows a cross sectional view of a portion of a backend structure 700B of integrated circuit die 100, including an example SiCr resistor 15 contacted by a metal plug.

FIG. 8 shows a cross-sectional view an example backend structure 800B in which metal plugs (e.g., metal-filled vias 22) extending from top surface S3 through sub interlevel dielectric layer 13D2 contact SiCr resistor 15. As shown in FIG. 8, SiCr resistor 15 is disposed on oxide layer 14 disposed on sub interlevel dielectric layer 13D1. A capping layer (e.g., oxide layer 17) overlays SiCr resistor 15. The oxide layers 14 and 17 protect bottom and top surfaces S1 and S2 of SiCr resistor 15. A pad 21 (e.g., a TiN pad) is disposed on oxide layer 17 in resistor head region 15RH of SiCr resistor 15. The TiN material of pad 21 also fills opening 17O in oxide layer 17 and contacts SiCr resistor 15 in resistor head region 15RH of SiCr resistor 15. A metal-filled via 22 (e.g., a W plug) extending from top surface S3 through sub interlevel dielectric layer 13D2 lands on pad 21 to contact resistor head region 15RH of SiCr resistor 15. Forming metal-filled via 22 may involve etching a via extending from top surface S3 through sub interlevel dielectric layer 13D2 using an oxide etchant that has a positive selectivity for oxide over TiN.

In some example implementations, depth control in etching of the vias extending from top surface S3 through sub interlevel dielectric layer 13D2 to contact SiCr resistor 15 can be achieved using landing pads (e.g., etch stops) to stop or terminate etching of the vias (e.g., at SiCr resistor 15).

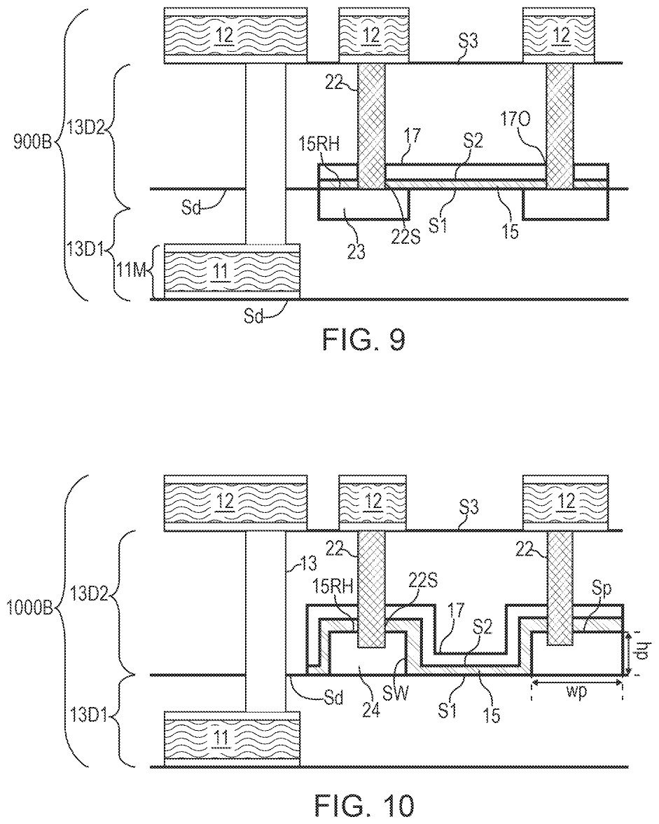

As an example, FIG. 9 shows a cross sectional view of a portion of a backend structure 900B of integrated circuit die 100, including an example SiCr resistor 15 contacted by a metal plug or metal-filled via that terminates at a landing pad.

As shown in FIG. 9, landing pads (e.g., landing pads 23) are formed in sub interlevel dielectric layer 13D1 below top surface Sd in alignment with resistor head 15RH regions of SiCr resistor 15). Landing pads 23 may, for example, be made of etch stop material (e.g., W, TiN or copper). Landing pads 23 may control a depth of etching required for forming metal-filled vias 22 extending from top surface S3 through sub interlevel dielectric layer 13D2. Metal plugs (e.g., metal-filled vias 22) etched from top surface S3 through sub interlevel dielectric layer 13D2 can punch through of SiCr resistor 15 to end on the landing pads. Electrical contact to SiCr resistor 15 may be established through sidewalls 22S of the metal plugs (e.g., metal-filled vias 22) as well as along the SiCr to TiN interface of landing pads 23.

As another example, FIG. 10 shows a cross sectional view of a portion of a backend structure 1000B of integrated circuit die 100, including an example SiCr resistor 15 contacted by a metal plug or metal-filled via that terminates at a landing pad (e.g., landing pad 24).

As shown in FIG. 10, landing pads (e.g., landing pads 24) may be formed on surface Sd of sub interlevel dielectric layer 13D1. Landing pads 24 may have a block shape (e.g., rectangular or cubical block) with vertical sides and atop surface. Landing pads 24 (block) may have, for example, a width wp and a height hp. Landing pads 24 may have vertical sides SW and a top surface Sp (e.g., at a height hp above surface Sd of sub interlevel dielectric layer 13D1). The landing pads (e.g., landing pads 24) may, for example, be made of metal or metallic materials (e.g., W, TiN or copper), and have etch stop selectivity relative to oxide or dielectric etchants.

SiCr resistor 15 formed as a sputtered thin film on surface Sd of sub interlevel dielectric layer 13D1 may conform to a topography of landing pads 24 disposed on surface Sd. SiCr resistor 15 may, for example, conformally extend over sides SW and top surfaces Sp of landing pads 24 so that regions of resistor (e.g., resistor heads 15RH) of resistor 15 are disposed on top surfaces Sp of landing pads 24. Metal plugs (e.g., metal-filled vias 22) etched from top surface S3 through sub interlevel dielectric layer 13D2 can punch through resistor heads 15RH of SiCr resistor 15 to end in the landing pads 24. Electrical contact to resistor heads 15RH may be established through sidewalls 22S of the metal plugs (e.g., metal-filled vias 22) as well as along the SiCr to TiN interface of landing pads 24.

The use of etch stops (e.g., landing pads 23, landing pads 24) in the backend structures 900B and 1000B as described above, for example, with reference to FIGS. 9 and 10, may obviate a need for precision of depth in etching of the metal-filled vias used to contact SiCr resistor 15.

In some example implementations, metal-filled vias may connect SiCr resistor 15 disposed over sub interlevel dielectric layer 13D1 to the metal lines (e.g., first metal level 11) in sub interlevel dielectric layer 13D1.

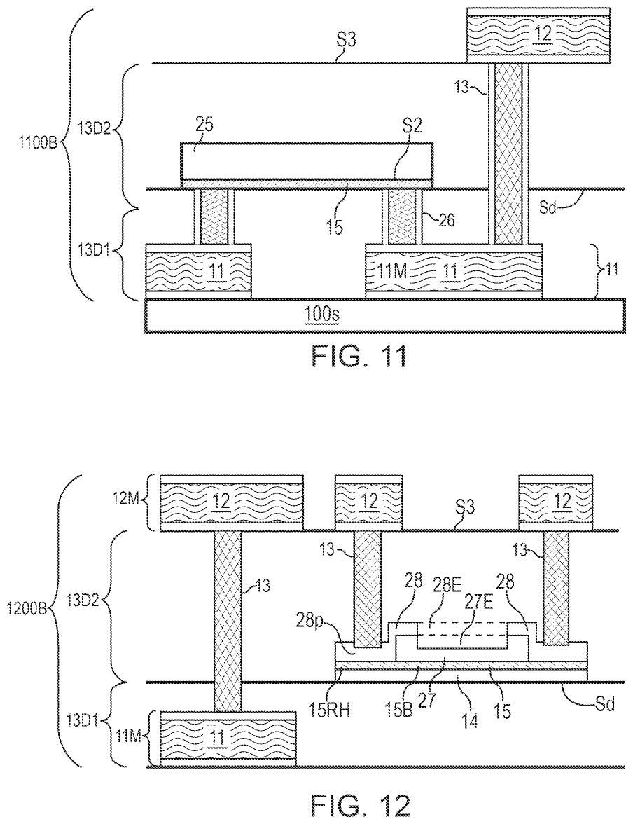

As an example, FIG. 11 shows a cross sectional view of a portion of a backend structure 1100B of integrated circuit die 100, including an example SiCr resistor 15 contacted by a metal-filled via extending between the resistor and first metal level 11 in metallization layer 11M.

In the example shown in FIG. 11, SiCr resistor 15 is patterned and formed on surface Sd of sub interlevel dielectric layer 13D1. A protective dielectric layer (e.g., dielectric layer 25) is disposed on top surface S2 of SiCr resistor 15. Dielectric layer 25 may, for example, be made of silicon nitride (SiN). Metal plugs or metal-filled vias 26 extend from first metal level 11 through sub interlevel dielectric layer 13D1 to contact bottom surface S1 of SiCr resistor 15. Metal-filled vias 26, like metal-filled vias 13, may be filled with metal including, for example, tungsten or other conductive metals or alloys. Metal-filled vias 26 extending only through sub interlevel dielectric layer 13D1 can be shorter in length (or height) than, for example, metal-filled vias 13 that may extend through both sub interlevel dielectric layer 13D1 and sub interlevel dielectric layer 13D1 in the metallization scheme of backend structure 1100B.

Metal-filled vias 26 may be formed in sub interlevel dielectric layer 13D1 before SiCr resistor 15 is patterned and formed on surface Sd of sub interlevel dielectric layer 13D1.

In some example implementations, metal or metallic pads disposed over SiCr resistor 15 can be used as landing pads for metal-filled vias to contact the resistor.

As an example, FIG. 12 shows a cross sectional view of a portion of a backend structure 1200B of integrated circuit die 100 including a SiCr resistor 15 contacted by a metal-filled via stopping in a metal or metallic pad disposed over the resistor.

In the example shown in FIG. 12, SiCr resistor 15 is formed on oxide layer 14 on surface Sd of sub interlevel dielectric layer 13D1. A protective dielectric layer (e.g., dielectric layer 27) is disposed on top surface S2 of SiCr resistor 15. Dielectric layer 27 may, for example, be a TEOS oxide layer patterned (using, e.g., a resistor body mask) to form a protective structure over body region (i.e., resistor body 15B) of the resistor.

Further, a landing pad 28p is disposed on resistor head 15RH of the resistor. Landing pad 28 may be made of metal or metallic material (e.g., W, TiN, or copper). Landing pad 28 can be formed by patterning and etching a metal layer deposited over dielectric layer 27 and resistor head 15RH portions of the resistor. FIG. 12 also shows portion 28E of the metal layer that is removed by the metal layer etching process, and portion 27E of dielectric layer 27 that may be removed by over etching in the metal layer etching process.

Dielectric layer 27 protects surfaces of at least the body portion (e.g., resistor body 15B) of the resistor from etchants in the metal layer etching process.

Metal plugs or metal-filled vias 13 etched from top surface S3 through sub interlevel dielectric layer 13D2 may land on (i.e., stop on) landing pads 28 above resistor head 15RH portions of the resistor to establish electrical connection with SiCr resistor 15.

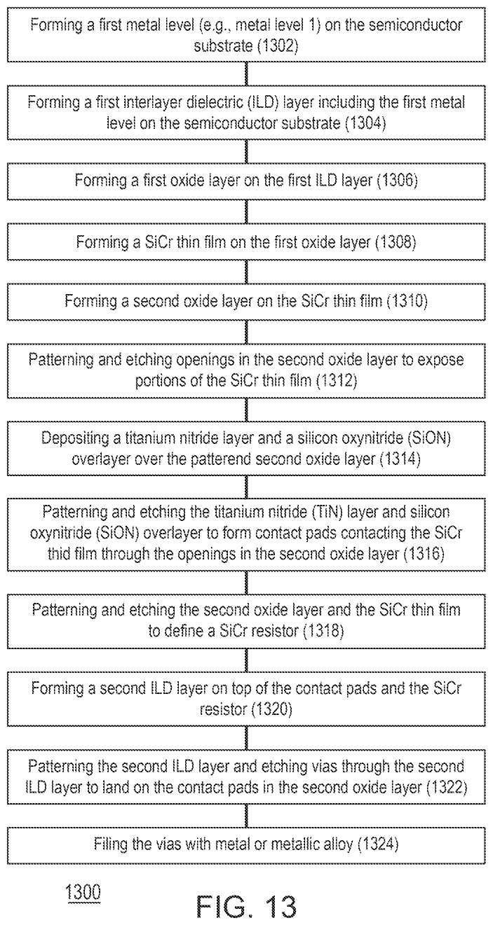

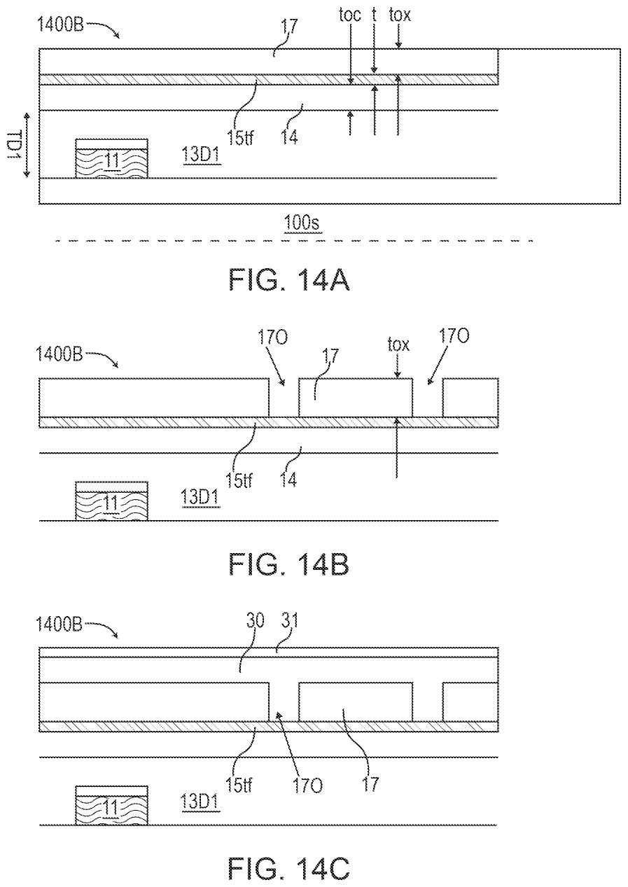

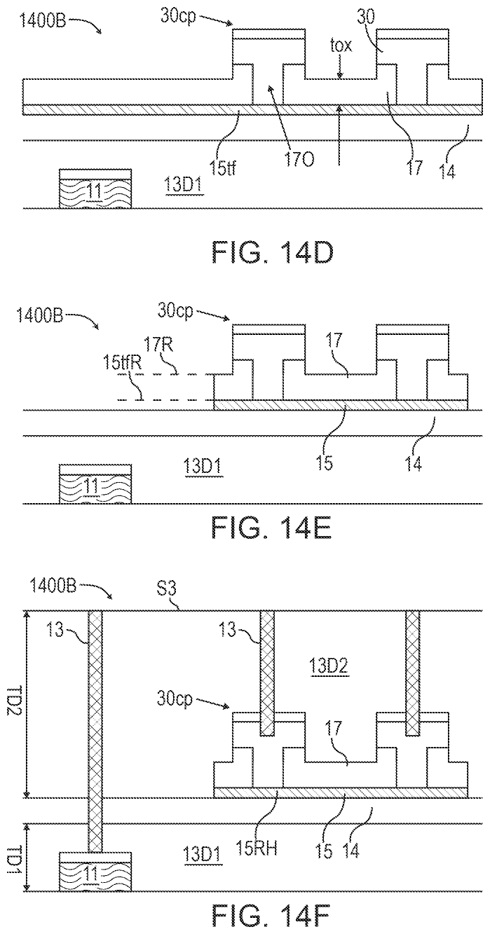

FIG. 13 shows an example method 1300 for integrating a SiCr resistor (e.g., SiCr resistor 15) in a backend structure (e.g., backend structure 1400B, FIG. 14F) disposed on a top surface S of a semiconductor substrate (e.g., semiconductor substrate 100s).

Method 1300 includes forming a first metal level (e.g., metal level 1) on the semiconductor substrate (1302); forming a first interlayer dielectric layer (ILD) on the semiconductor substrate including the first metal level (1304); depositing a first oxide layer on the first ILD (1306); forming a SiCr thin film on the first oxide layer (1308); depositing a second oxide layer on the SiCr thin film (1310).

Method 1300 further includes patterning and etching openings in the second oxide layer to expose portions of the SiCr thin film (1312); depositing a titanium nitride (TiN) layer and a silicon oxynitride (SiON) overlayer over the patterned second oxide layer (1314); patterning and etching the titanium nitride (TiN) layer and silicon oxynitride (SiON) overlayer to form contact pads contacting the SiCr thin film through the openings in the second oxide layer (1316); patterning and etching the second oxide layer and the SiCr thin film to define a SiCr resistor (1318).

Method 1300 further includes forming a second ILD layer on top of the contact pads and the SiCr resistor (1320); patterning the second ILD layer and etching vias through the second ILD layer to land on the contact pads in the second oxide layer (1322); and filling the vias with metal or metallic alloy (1324).

FIGS. 14A-14F show cross sectional views of a backend structure 1400B disposed on semiconductor substrate 100s at different stages of fabrication or after different steps of method 1300 for integrating the SiCr resistor in the backend structure.

FIG. 14A shows backend structure 1400B at a first stage (e.g., after method 1300, step 1310). As shown in the FIG. 14A, at the first stage, backend structure 1400B includes a first interlayer dielectric layer (ILD) (e.g., layer 13D1) enclosing a first metal level (e.g., metal level 11) disposed on semiconductor substrate 100s. Layer 13D1 may be formed by depositing oxide on metal lines (e.g., metal level 11) formed on substrate 100s. Layer 13D1 may, for example, be made by TEOS deposition, and may have a thickness TD1 in a range of about a thousand angstrom to a few thousands of angstroms (e.g., 3000 A) after an oxide CMP planarization step. Layer 13D1 may be covered by a capping oxide layer (e.g., oxide layer 14).

Oxide layer 14 may, for example, be made by TEOS deposition and may have a thickness toc in a range of about a few hundreds of angstroms to about a few thousands of angstroms (e.g., 1000 A). A thin film of silicon chromium material (e.g., SiCr thin film 15tf) is deposited on oxide layer 14, for example, by sputtering or co-sputtering materials including silicon and chromium. Further, another capping oxide layer (e.g., oxide layer 17) is disposed on SiCr thin film 15tf. Oxide layer 17, like oxide layer 14, may, for example, be made by TEOS deposition, and may have a thickness tox in a range of about a hundred angstroms to about few thousands of angstroms (e.g., 1000 A).

SiCr thin film 15tf may have a thickness tin a range of about 40 A to about 100 A (e.g., 60-90A). SiCr thin film 15tf can be a precursor material for the SiCr resistor (e.g., SiCr resistor 15, FIG. 14D) formed in backend structure 1400B at later stages. SiCr thin film 15tf may be annealed after sputter deposition of its components (silicon, chromium, etc.) to, for example, activate its resistive properties. SiCr thin film 15tf may be annealed, for example, at a temperature in the range of about 400C to 425C. In example implementations, annealed SiCr thin film 15tf may have a resistivity in a range of about a few hundred to a few thousand ohm/sq. (e.g., 1000 ohm/sq.).

FIG. 14B shows backend structure 1400B at a second stage (e.g., after method 1300, step 1310). As shown in the FIG. 14B, at the second stage, openings 140 are formed in oxide layer 17 to expose portions of the underlying SiCr thin film 15tf. The portions of the underlying SiCr thin film 15tf exposed in openings 17O may later form resistor head portions (e.g., resistor head 15RH of SiCr resistor 15). In example implementations, an i-line resist coating applied to oxide layer 17 may be lithographical patterned using a mask (e.g. a resistor head mask, Mask 3, FIG. 1B)) to define openings 140 corresponding to the resistor head portions of SiCr resistor 15. After a UV resist bake, openings 17O may be etched in oxide layer 17 using, for example, a wet etch having a high selectivity to silicon-chromium. The resist may be stripped with a no ash or a mild ash process without damaging the SiCr thin film 15tf.

FIG. 14C shows backend structure 1400B at a third stage (e.g., after method 1300, step 1314). As shown in the FIG. 14C, at the third stage, a TiN layer 30 is deposited in opening 17O and over oxide layer 17. TiN layer 30 may have a thickness in a range of about 1000A to 2000A (e.g., 1500A). Further, a silicon oxynitride etch stop layer/anti-reflective coating (ARC) (e.g., SiON layer 31) may be deposited over TiN layer 30. SiON layer 31 may have a thickness in a range of about 200A to 800A (e.g., 300A).

FIG. 14D shows backend structure 1400B at a fourth stage (e.g., after method 1300, step 1316). As shown in the FIG. 14D, at the fourth stage, portions of TiN layer 30 (and SiON layer 31) over oxide layer 17 are patterned using a SiCr- contact mask (e.g. a Mask 2, FIG. 1B)) and removed (i.e., etched) to define contact pads 30cp that contact SiCr thin film 15tf through openings 17O in the oxide layer 17. The portions of TiN layer 30 (and SiON layer 31) that are not removed and remain to form contact pads 30cp are lithographically defined by the SiCr- contact mask (e.g. a Mask 2, FIG. 1B)).

FIG. 14E shows backend structure 1400B at a fifth stage (e.g., after method 1300, step 1318). As shown in the FIG. 14E, at the fifth stage, portions (e.g., portions 17R and 15 tfR) of oxide layer 17 and SiCr thin film 15tf are patterned using a mask (e.g. a Mask 1, FIG. 1B)) and are removed (i.e., etched) to define SiCr resistor 15 disposed on oxide layer 14.

FIG. 14F shows backend structure 1400B at a sixth stage (e.g., after method 1300, step 1324). As shown in the FIG. 14F, at the sixth stage, a second interlayer dielectric layer (ILD) (e.g., layer 13D2) is disposed on the first interlayer dielectric layer (ILD) (i.e., layer 13D1) to enclose SiCr resistor 15 and contact pads 30cp. Layer 13D2 may be formed, for example, by TEOS deposition and may have a thickness TD2 in a range of about a thousand angstroms to about a few thousand angstroms (e.g., 5500 A).

As shown in the FIG. 14F, at the sixth stage, metal-filled vias 13 extend from top surface S3 of layer 13D2 to reach contact pads 30cp that are in contact with resistor head portions (e.g., resistor head 15RH) of SiCr resistor 15. Other metal-filled vias 13 may extend from top surface S3 of layer 13D2 to reach first metal level 11 in layer 13D1.

In example implementations, initially a thicker (e.g., about 8000 angstroms) TEOS oxide layer may be deposited to form an initial layer 13D2 (not shown). Top surface S3 of layer 13D2 may be prepared by chemical-mechanical-polishing (CMP) of the initial layer. The CMP may remove some of the deposited oxide (e.g., 3000 A of oxide) and reduce the thickness of layer 13D2 (e.g., to about 5500 A). Formation of vias 13 may include, lithograph patterning of top surface S3 (using a mask) to define locations of the vias and etching the vias (e.g., using an oxide etchant) through layer 13D2 to reach contact pads 30cp (and on metal level 1). Contact pads 30cp may act as etch stops for the etching. The etched vias may be lined with a TiN liner and filled with metal or metallic alloy. In an example implementation, vias 13 may be filled with sputtered tungsten (W). A tungsten CMP step may be performed to remove excess W, if any is deposited on surface S3 in via filling processes.

The surfaces of SiCr resistor 15 remain protected by oxide layer 17 from exposure to etchants during the etching processes used in the fabrication of backend structure 1400B.

In at least one general aspect, a method can include forming an interlayer dielectric (ILD) layer including a first metal level on a semiconductor substrate, and/or forming a first oxide layer on the ILD layer. The method can include forming a SiCr thin film on the first oxide layer, forming a second oxide layer on the SiCr thin film, and/or patterning and etching openings in the second oxide layer to expose portions of the SiCr thin film. The method can include depositing a titanium nitride (TiN) layer and a silicon oxynitride (SiON) overlayer over the patterned second oxide layer, patterning and etching the titanium nitride (TiN) layer and silicon oxynitride (SiON) overlayer to form contact pads contacting the SiCr thin film through the openings in the second oxide layer, and/or patterning and etching the second oxide layer and the SiCr thin film to define a SiCr resistor.

In some implementations, the ILD layer is a first ILD layer. The method can include forming a second ILD layer on top of the contact pads and the SiCr resistor, patterning the second ILD layer and etching vias through the second ILD layer to land on the contact pads in the second oxide layer, and/or filling the vias with metal or metallic alloy.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An integrated circuit die comprising:
a silicon chromium (SiCr) thin film resistor disposed on a first oxide layer, the SiCr thin film resistor having a resistor body and a resistor head;
a second oxide layer overlaying the SiCr thin film resistor, the second oxide layer having an opening exposing a surface of the resistor head;
a metal pad disposed in the opening in the second oxide layer, the metal pad being in contact with the surface of the resistor head exposed by the opening;
an interlevel dielectric layer disposed on the second oxide layer overlaying the SiCr thin film resistor; and
a metal-filled via extending from a top surface of interlevel dielectric layer through the interlevel dielectric layer and contacting the metal pad disposed in the opening in the second oxide layer.

2. The integrated circuit die of claim 1, wherein the SiCr thin film resistor has a thickness in a range of about 40 angstroms to about 100 angstroms.

3. The integrated circuit die of claim 1, wherein a top surface of the metal pad and a top surface of the second oxide layer are about co-planar.

4. The integrated circuit die of claim 1, wherein a thickness of the metal pad disposed in the opening in the second oxide layer is less than a thickness of the oxide layer.

5. The integrated circuit die of claim 1, wherein the SiCr thin film resistor comprises an amorphous silicon-chromium thin film with a weight % of Cr between 40% and 60% and a weight % of C between 0% and 15%.

6. The integrated circuit die of claim 1, wherein the metal-filled via includes a titanium nitride (TiN) liner, and is filled with tungsten (W) metal.

7. An integrated circuit die comprising:
a silicon chromium (SiCr) thin film resistor disposed on a first oxide layer, the SiCr thin film resistor having a resistor body and a resistor head;
a protective dielectric layer overlaying the SiCr thin film resistor;
an interlevel dielectric layer disposed on the protective dielectric layer overlaying the SiCr thin film resistor; and
a metal-filled via extending from a top surface of interlevel dielectric layer through the interlevel dielectric layer and the protective dielectric layer and contacting the resistor head of SiCr thin film resistor.

8. The integrated circuit die of claim 7, wherein the SiCr thin film resistor has a thickness in a range of about 40 angstroms to about 100 angstroms.

9. The integrated circuit die of claim 7, wherein the protective dielectric layer is a silicon nitride layer having a thickness in a range of about 200 angstroms to about 800 angstroms.

10. The integrated circuit die of claim 7, wherein the metal-filled via extending from the top surface of interlevel dielectric layer punches through the SiCr thin film resistor and contacts the SiCr thin film resistor through side walls of the metal-filled via.

11. The integrated circuit die of claim 10, wherein the metal-filled via punching through the SiCr thin film resistor terminates at a landing pad disposed below the SiCr thin film resistor.

12. The integrated circuit die of claim 10, wherein the metal-filled via terminates at a landing pad disposed above the SiCr thin film resistor.

13. An integrated circuit die comprising:
a silicon chromium (SiCr) thin film resistor disposed on a first oxide layer, the SiCr thin film resistor having a resistor body and a resistor head;
an interlevel dielectric layer disposed on a dielectric layer overlaying the SiCr thin film resistor; and
a metal-filled via extending from a top surface of interlevel dielectric layer through the interlevel dielectric layer and contacting the resistor head of SiCr thin film resistor, the metal-filled via terminating at a landing pad disposed in the die.

14. The integrated circuit die of claim 13, wherein the SiCr thin film resistor has a thickness in a range of about 40 angstroms to about 100 angstroms.

15. The integrated circuit die of claim 13, wherein the landing pad includes metal or metallic material.

16. The integrated circuit die of claim 13, wherein the landing pad is aligned with and disposed above the resistor head of the SiCr thin film resistor and the first oxide layer and includes a portion disposed in an opening in the first oxide layer in contact with the resistor head of the SiCr thin film resistor.

17. The integrated circuit die of claim 13, wherein the landing pad is disposed on the first oxide layer, the landing pad having vertical sides and a top surface, wherein the resistor head of the SiCr thin film resistor is disposed on the top surface of the landing pad, and wherein the metal-filled via punches through the SiCr thin film resistor and contacts the resistor head through sidewalls of the metal-filled via

18. The integrated circuit die of claim 13, wherein the landing pad is aligned with and disposed below the resistor head of the SiCr thin film resistor, and wherein the metal-filled via punches through the resistor head and contacts the resistor head through sidewalls of the metal-filled via.

19. An integrated circuit die comprising:
an interlevel dielectric (ILD) layer disposed on a substrate, the ILD layer including a first metal level disposed on the substrate;
a metal-filled via extending from a top surface of the ILD layer through the ILD layer to contact the first metal level;
a silicon chromium (SiCr) thin film resistor disposed on the top surface of the ILD layer, a bottom surface of the SiCr thin film resistor being in contact with the metal-filled via extending from the first metal level to the top surface of the ILD layer.

20. The integrated circuit die of claim 19, further comprising a silicon nitride layer disposed on a top surface the SiCr thin film resistor.

21. The integrated circuit die of claim 19, wherein the ILD layer is a first ILD layer, and the integrated circuit die further comprises a second ILD layer disposed on the top surface the SiCr thin film resistor and the top surface of the first ILD layer.

22. An integrated circuit die comprising:
an interlevel dielectric (ILD) layer disposed on a substrate, the ILD layer including:
a silicon chromium (SiCr) thin film resistor disposed on a first oxide layer, the SiCr thin film resistor having a resistor body and a resistor head;
an oxide layer overlaying the resistor body of the SiCr thin film resistor;
a landing pad disposed on and in contact with the resistor head of the SiCr thin film resistor;
and a metal-filled via extending from a top surface of the ILD layer through the ILD layer to contact the landing pad disposed on and in contact with the resistor head.

23. The integrated circuit die of claim 22, wherein the landing pad include titanium nitride (TiN).

24. The integrated circuit die of claim 22, wherein the oxide layer overlaying the resistor body includes tetraethyl orthosilicate (TEOS) oxides.
